(19) United States
(12) Patent Application Publication
(10) Pub. No.: US 2018/0190501 A1
(43) Pub. Date: Jul. 5, 2018

(54) PLASMA PROCESSING APPARATUS

(71) Applicant: TOKYO ELECTRON LIMITED, Tokyo (JP)

(72) Inventor: Takehiro UEDA, Miyagi (JP)

(73) Assignee: TOKYO ELECTRON LIMITED, Tokyo (JP)

(21) Appl. No.: 15/861,014

(22) Filed: Jan. 3, 2018

(30) Foreign Application Priority Data
Jan. 5, 2017 (JP) 2017-000552
Nov. 21, 2017 (JP) 2017-223970

(51) Int. Cl. H01L 21/3065; H01L 21/67; H01L 21/683

(52) U.S. Cl. CPC H01L 21/3065; H01L 21/67069; H01L 21/6831; H01L 21/67248; H01L 21/67103

(57) ABSTRACT

Disclosed is a plasma processing apparatus including: a first placing table including a placing surface configured to place thereon a workpiece serving as a plasma processing target, an outer peripheral surface, a heater provided on the placing surface, a power supply terminal provided on a back surface side opposite to the placing table, and a wiring provided on the outer peripheral surface so as to be enclosed in an insulator, the wiring being configured to connect the heater and the power supply terminal; and a second placing table provided along the outer peripheral surface of the first placing table and configured to place a focus ring thereon.

### CROSS-REFERENCE TO RELATED APPLICATIONS

This application is based on and claims priority from Japanese Patent Application Nos. 2017-000552 and 2017-223970 filed on Jan. 5, 2017 and Nov. 21, 2017, respectively, with the Japan Patent Office, the disclosures of which are incorporated herein in their entirety by reference.

### TECHNICAL FIELD

Various aspects and exemplary embodiments of the present disclosure relate to a plasma processing apparatus.

### BACKGROUND

In the related art, there has been known a plasma processing apparatus that performs a plasma processing (e.g., etching) on a workpiece (e.g., a semiconductor wafer) by using plasma. In such a plasma processing apparatus, it is important to control the temperature of the workpiece in order to implement the in-plane uniformity of the processing of the workpiece. Therefore, the plasma processing apparatus may have a temperature adjustment heater embedded in a placing table on which the workpiece is placed in order to perform a higher degree of temperature control. It is necessary to supply power to the heater. Therefore, in the plasma processing apparatus, a power supply terminal is provided in an outer peripheral region of the placing table, and power is supplied from the power supply terminal to the heater (see, e.g., Japanese Patent Laid-Open Publication No. 2016-001688).

### SUMMARY

According to an aspect of the present disclosure, there is provided a plasma processing apparatus having a first placing table and a second placing table. The first placing table has a placing surface configured to place a workpiece serving as a plasma processing target thereon and an outer peripheral surface. In the first placing table, a heater is provided on the placing surface, and a power supply terminal is provided on a back surface side opposite to the placing surface. In the first placing table, a wiring is provided on the outer peripheral surface so as to be enclosed in an insulator and configured to connect the heater and the power supply terminal. The second placing table is provided along the outer peripheral surface of the first placing table and configured to place a focus ring thereon.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating a schematic configuration of a plasma processing apparatus according to an exemplary embodiment.

FIG. 2 is a schematic cross-sectional view illustrating a configuration of a main part of first and second placing tables according to a first exemplary embodiment.

FIG. 3 is a view illustrating an example of a region in which heaters are arranged.

FIG. 4 is a plan view illustrating an example of a green sheet.

FIG. 5 is a view illustrating an example of a method for manufacturing an insulating portion.

FIG. 6 is a schematic cross-sectional view illustrating a configuration of a main part of first and second placing tables according to a second exemplary embodiment.

FIGS. 7A to 7E are views for explaining a method for manufacturing an electrostatic chuck and an insulating portion according to the second exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In a plasma processing apparatus, a focus ring is disposed around a placement region of a workpiece. However, when a power supply terminal is provided in the outer peripheral region of the placing table as described in Japanese Patent Laid-Open Publication No. 2016-001688, the power supply terminal is arranged outside the placement region on which the workpiece is placed. Thus, the size of the placing table in the radial direction becomes large. In the plasma processing apparatus, when the size of the placing table in the radial direction becomes large, the overlapping portion between the focus ring and the outer peripheral region of the placing table provided with the power supply terminal becomes large. Thus, unevenness tends to occur in the temperature of the focus ring in the radial direction. In the plasma processing apparatus, when unevenness occurs in the temperature of the focus ring in the radial direction, the in-plane uniformity of the plasma processing on the workpiece deteriorates.

According to an aspect of the present disclosure, there is provided a plasma processing apparatus having a first placing table and a second placing table. The first placing table has a placing surface configured to place a workpiece serving as a plasma processing target thereon and an outer peripheral surface. In the first placing table, a heater is provided on the placing surface, and a power supply terminal is provided on a back surface side opposite to the placing surface. In the first placing table, a wiring is provided on the outer peripheral surface so as to be enclosed in an insulator and configured to connect the heater and the power supply terminal. The second placing table is provided along the outer peripheral surface of the first placing table and configured to place a focus ring thereon.

In the above-described plasma processing apparatus, the second placing table includes a heater provided on a placing surface on which the focus ring is placed.

In the above-described plasma processing apparatus, the first placing table includes a coolant flow path formed therein.

In the above-described plasma processing apparatus, in the first placing table, a plurality of heaters are provided for respective regions obtained by dividing the placing surface, and a plurality of power supply terminals are provided on the back surface side. The insulator is formed in a ring shape so as to surround the outer peripheral surface of the first placing table, and a plurality of wirings connecting the plurality of heaters and the plurality of power supply terminals are provided on the outer peripheral surface so as to be dispersedly enclosed in the insulator.

In the above-described plasma processing apparatus, the insulator is formed of a ceramic having a thermal conductivity lower than that of the first placing table.

In the above-described plasma processing apparatus, the insulator is formed with a gap of a predetermined distance between the insulator and the outer peripheral surface.

In the above-described plasma processing apparatus, the insulator is formed by stacking and sintering sheet-like ceramic materials each provided with a conductive portion serving as the wiring.

In the above-described plasma processing apparatus, the insulator includes a conductive layer configured to function as the wiring and formed by thermal spraying of a conductive metal in an insulating layer formed by thermal spraying of a conductive metal.

According to an aspect of the plasma processing apparatus of the present disclosure, it is possible to suppress occurrence of unevenness in the temperature of the focus ring in the radial direction.

Hereinafter, exemplary embodiments of the plasma processing apparatus disclosed herein will be described in detail with reference to drawings. Meanwhile, in the respective drawings, the same or corresponding parts will be denoted by the same symbols. Further, the present disclosure is not limited to the exemplary embodiments disclosed herein. The respective exemplary embodiments may be appropriately combined within a range that does not contradict the processing contents.

### First Exemplary Embodiment

[Configuration of Plasma Processing Apparatus]

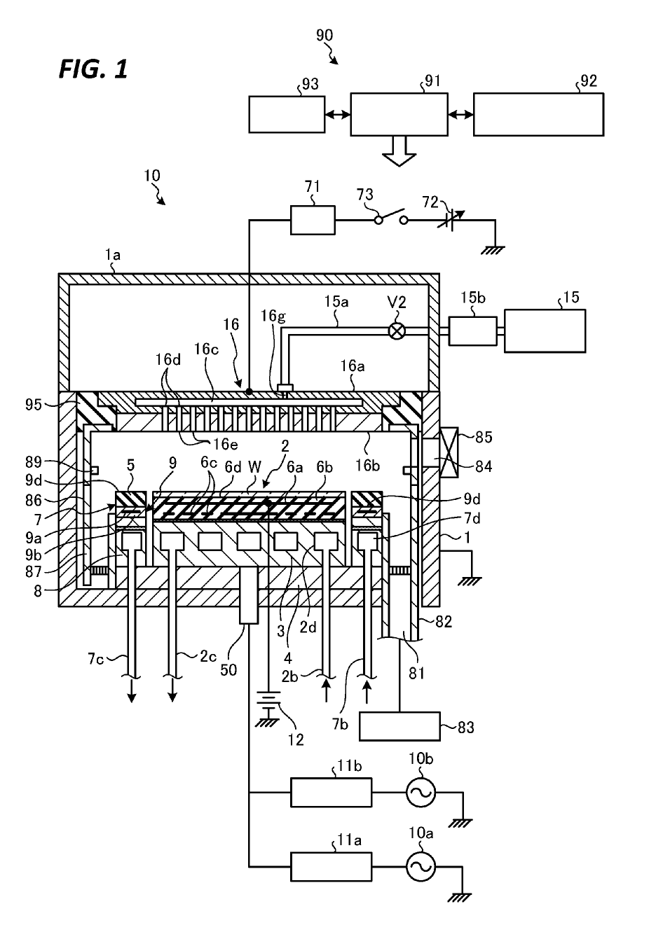

First, descriptions will be made on a schematic configuration of a plasma processing apparatus 10 according to the exemplary embodiment. FIG. 1 is a schematic cross-sectional view illustrating a schematic configuration of the plasma processing apparatus according to the exemplary embodiment. The plasma processing apparatus 10 includes a processing container 1 that is airtightly constituted and electrically grounded. The processing container 1 has a cylindrical shape and is made of, for example, aluminum having an anodized film formed on the surface thereof. The processing container 1 defines a processing space in which plasma is generated. A first placing table 2 is accommodated in the processing container 1 and configured to horizontally support a semiconductor wafer (hereinafter, simply referred to as a “wafer”) which is a workpiece.

The first placing table 2 has a substantially columnar shape having top and bottom surfaces which face upward and downward, respectively, and the top surface serves as a placing surface 6d on which the wafer W is placed. The placing surface 6d of the first placing table 2 is approximately the same size as the wafer W. The first placing table 2 includes a base 3 and an electrostatic chuck 6.

The base 3 is made of a conductive metal, for example, aluminum. The base 3 functions as a lower electrode. The base 3 is supported by a supporting stand 4 of an insulator, and the supporting stand 4 is installed at the bottom portion of the processing container 1.

The electrostatic chuck 6 is formed in a disc shape with a flat top surface, and the top surface serves as the placing surface 6d on which the wafer W is placed. The electrostatic chuck 6 is provided at the center of the first placing table 2 in a plan view. The electrostatic chuck 6 includes an electrode 6a and an insulator 6b. The electrode 6a is provided inside the insulator 6b, and a DC power supply 12 is connected to the electrode 6a. The electrostatic chuck 6 is configured to attract the wafer W by a Coulomb force when a DC voltage is applied from the DC power supply 12 to the electrode 6a. Further, in the electrostatic chuck 6, a heater 6c is provided inside the insulator 6b. The heater 6c is supplied with power via a power supply mechanism (to be described later) to control the temperature of the wafer W.

A second placing table 7 is provided around the outer peripheral surface of the first placing table 2. The second placing table 7 is formed in a cylindrical shape whose inner diameter is larger than the outer diameter of the first placing table 2 by a predetermined size and is disposed coaxially with the first placing table 2. The second placing table 7 has a top surface serving as a placing surface 9d on which an annular focus ring 5 is placed. The focus ring 5 is formed of, for example, single crystal silicon, and is placed on the second placing table 7.

The second placing table 7 includes a base 8 and a focus ring heater 9. The base 8 is made of, for example, aluminum having an anodized film formed on the surface thereof. The base 8 is supported by the supporting stand 4. The focus ring heater 9 is supported by the base 8. The focus ring heater 9 is formed in an annular shape with a flat top surface, and the top surface serves as the placing surface 9d on which the focus ring 5 is placed. The focus ring heater 9 includes an electrode 9a and an insulator 9b. The heater 9a is provided inside the insulator 9b and is enclosed in the insulator 9b. The heater 9a is supplied with power via a power supply mechanism (to be described later) to control the temperature of the focus ring 5. In this manner, the temperature of the wafer W and the temperature of the focus ring 5 are independently controlled by different heaters.

A power feed rod 50 is connected to the base 3. The power feed rod 50 is connected with a first RF power supply 10a via a first matching unit 11a and a second RF power supply 10b via a second matching unit 11b. The first RF power supply 10a is a power supply for plasma generation, and a high frequency power of a predetermined frequency is supplied from the first RF power supply 10a to the base 3 of the first placing table 2. Further, the second RF power supply 10b is a power supply for ion drawing (bias), and a high frequency power of a predetermined frequency lower than that of the first RF power supply 10a is supplied from the second RF power supply 10b to the base 3 of the first placing table 2.

A coolant flow path 2d is formed inside the base 3. A coolant inlet pipe 2b is connected to one end of the coolant flow path 2d, and a coolant outlet pipe 2c is connected to the other end of the coolant flow path 2d. Further, a coolant flow path 7d is formed inside the base 8. A coolant inlet pipe 7b is connected to one end of the coolant flow path 7d, and a coolant outlet pipe 7c is connected to the other end of the coolant flow path 7d. The coolant flow path 2d is positioned below the wafer W and functions to absorb the heat of the wafer W. The coolant flow path 7d is positioned below the focus ring 5 and functions to absorb the heat of the focus ring 5. The plasma processing apparatus 10 is configured to individually control the temperatures of the first placing table 2 and the second placing table 7 by circulating a coolant (e.g., cooling water) in the coolant flow path 2d and the coolant flow path 7d, respectively. The plasma processing apparatus 10 may be configured to individually control the temperatures by supplying a cold heat transfer gas to the back surface side of the wafer W or the focus ring 5. For example, a gas supply pipe for supplying a cold heat transfer gas (backside gas) (e.g., helium gas) may be provided on the back surface of the wafer W so as to penetrate, for example, the first placing table 2. The gas supply pipe is connected to a gas source. With the configuration, the wafer W attracted and held on the top surface of the first placing table 2 by the electrostatic chuck 6 may be controlled to a predetermined temperature.

Meanwhile, a shower head 16 functioning as an upper electrode is provided above the first placing table 2 so as to face the first placing table 2 in parallel. The shower head 16 and the first placing table 2 function as a pair of electrodes (upper and lower electrodes).

The shower head 16 is provided on the ceiling wall portion of the processing container 1. The shower head 16 includes a main body 16a and an upper top plate 16b forming an electrode plate, and is supported in an upper portion of the processing container 1 via an insulating member 95. The main body 16a is made of a conductive material, for example, aluminum of which the surface is anodized, and is configured such that the upper top plate 16b is detachably supported under the main body 16a.

A gas diffusion chamber 16c is provided inside the main body 16a, and a plurality of gas flow holes 16d are formed in the bottom portion of the main body 16a so as to be positioned under the gas diffusion chamber 16c. In addition, gas introduction holes 16e are provided in the upper top plate 16b to penetrate the upper top plate 16b in the thickness direction and overlap with the gas flow holes 16d. With the configuration, the processing gas supplied to the gas diffusion chamber 16c is diffused in a shower form through the gas flow holes 16d and the gas introduction holes 16e and supplied into the processing container 1.

The main body 16a includes a gas introduction port 16g to introduce a processing gas to the gas diffusion chamber 16c. The gas introducing port 16g is connected with one end of a gas supply pipe 15a. The other end of the gas supply pipe 15a is connected with a processing gas source 15 that supplies a processing gas. The gas supply pipe 15a is provided with a mass flow controller (MFC) 15b and an opening/closing valve V2 in this order from the upstream side. Then, a processing gas for plasma etching is supplied from the processing gas source 15 to the gas diffusion chamber 16c through the gas supply pipe 15a, diffused in a shower form from the gas diffusion chamber 16c through the gas flow holes 16d and the gas introduction holes 16e, and supplied into the processing container 1.

The shower head 16 serving as an upper electrode is electrically connected with a variable DC power supply 72 via a low pass filter (LPF) 71. The variable DC power supply 72 is capable of turning on/off the power supply by an ON/OFF switch 73. The current and voltage of the variable DC power supply 72 and the ON/OFF of the ON/OFF switch 73 are controlled by a controller 90 (to be described later). As described later, when high frequency waves are applied from the first RF power supply 10a and the second RF power supply 10b to the first placing table 2 to generate plasma in the processing space, the ON/OFF switch 73 is turned on by the controller 90 so that a predetermined DC voltage is applied to the shower head 16 serving as an upper electrode.

In addition, a cylindrical ground conductor 1a is provided to extend from the side wall of the processing container 1 to a position higher than the height position of the shower head 16. The cylindrical ground conductor 1a has a ceiling wall in the upper portion thereof.

An exhaust port 81 is formed in the bottom portion of the processing container 1, and a first exhaust device 83 is connected to the exhaust port 81 via an exhaust pipe 82. The first exhaust device 83 includes a vacuum pump which, when operated, decompresses the interior of the processing container 1 to a predetermined degree of vacuum. Meanwhile, a carry-in/out port 84 for the wafer W is provided on a side wall in the processing container 1, and a gate valve 85 is provided in the carry-in/out port 84 to open and close the carry-in/out port 84.

On the inner side of the lateral portion of the processing container 1, a deposit shield 86 is provided along the inner wall surface. The deposit shield 86 suppresses any etching byproduct (deposit) from being attached to the processing container 1. A conductive member (GND block) 89 connected to the ground in a potential-controlled manner is provided at substantially the same height position as the wafer W of the deposit shield 86. Thus, abnormal discharge is suppressed. In addition, a deposit shield 87 is provided at the lower end portion of the deposit shield 86 to extend along the first placing table 2. The deposition shields 86 and 87 are configured to be detachable.

The operation of the plasma processing apparatus 10 having the above configuration is generally controlled by the controller 90. The controller 90 is provided with a process controller 91 that includes a CPU and controls each part of the plasma processing apparatus 10, a user interface 92, and a memory 93.

The user interface 92 includes, for example, a keyboard for inputting commands by a process manager to manage the plasma processing apparatus 10, and a display for visually displaying the operation status of the plasma processing apparatus 10.

The memory 93 stores a control program (software) for implementing various processings performed in the plasma processing apparatus 10 by the control of the process controller 91, or recipe in which, for example, a processing condition data is stored. Then, an arbitrary recipe is called from the memory 93 by an instruction from the user interface 92 as necessary, and executed by the process controller 91. Therefore, a desired processing is performed in the plasma processing apparatus 10 under the control of the process controller 91. Further, the control program or the recipe of, for example, the processing condition data may be used in a state of being stored in a computer-readable computer storage medium (e.g., a hard disc, a CD, a flexible disc, or a semiconductor memory), or may be used on-line by being transmitted at any time from other devices, for example, through a dedicated line.

[Configuration of First and Second Placing Tables]

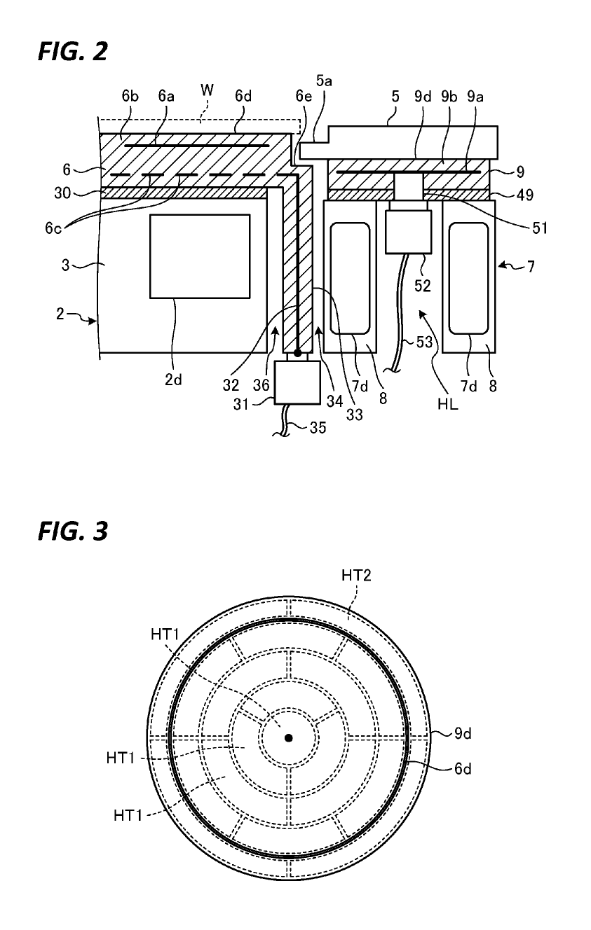

Next, descriptions will be made on the configuration of the main part of the first placing table 2 and the second placing table 7 according to a first exemplary embodiment with reference to FIG. 2. FIG. 2 is a schematic cross-sectional view illustrating the configuration of the main part of the first and second placing tables according to the first exemplary embodiment.

The first placing table 2 includes a base 3 and an electrostatic chuck 6. The electrostatic chuck 6 is attached to the base 3 via an insulating layer 30. The electrostatic chuck 6 has a disc shape and is provided to be coaxial with the base 3. In the electrostatic chuck 6, an electrode 6a is provided inside an insulator 6b. The top surface of the electrostatic chuck 6 serves as a placing surface 6d on which a wafer W is placed. At the lower end of the electrostatic chuck 6, a flange portion 6e is formed to protrude radially outward of the electrostatic chuck 6. That is, the outer diameter of the electrostatic chuck 6 differs depending on the position of the lateral surface.

In the electrostatic chuck 6, a heater 6c is provided inside the insulator 6b. The heater 6c may not be present inside the insulator 6b. For example, the heater 6c may be attached to the back surface of the electrostatic chuck 6 or interposed between the placing surface 6d and a coolant flow path 2d. Further, the heater 6c may be provided solely on the entire region of the placing surface 6d or may be provided individually for each divided region of the placing surface 6d. That is, a plurality of heaters 6c may be provided individually for respective divided regions of the placing surface 6d. For example, the placing surface 6d of the first placing table 2 may be divided into a plurality of regions according to the distance from the center, and the heaters 6c may extend annularly to surround the center of the first placing table 2 in the respective regions. Alternatively, the electrostatic chuck 6 may include a heater for heating the central region and a heater extending annularly to surround the central region. Further, a region extending annularly to surround the center of the placing surface 6d may be divided into a plurality of regions according to the direction from the center, and a heater 6c may be provided in each region.

FIG. 3 is a view illustrating an example of a region in which heaters are arranged. FIG. 3 is a top plan view of the first placing table 2 and the second placing table 7 when viewed from the top. In FIG. 3, the placing surface 6d of the first placing table 2 is illustrated in a disc shape. The placing surface 6d is divided into a plurality of regions HT1 according to the distance and direction from the center, and the heater 6c is provided individually in each of the regions HT1. Therefore, the plasma processing apparatus 10 may control the temperature of the wafer W for each of the regions HT1.

The descriptions will refer back to FIG. 2. The first placing table 2 is provided with a power supply mechanism for supplying power to the heater 6c. This power supply mechanism will be described. The first placing table 2 is provided with a power supply terminal 31 on the back surface side opposite to the placing surface 6d. That is, the power supply terminal 31 is disposed on the opposite side of the electrostatic chuck 6 of the base 3. The power supply terminal 31 is provided corresponding to the heater 6c provided on the placing surface 6d. Further, in the case where a plurality of heaters 6c are provided on the placing surface 6d, a plurality of power supply terminals 31 are also provided to correspond to the heaters 6c. In addition, the first placing table 2 is provided with an insulating portion 33 enclosing a wiring 32 connecting the heater 6c and the power supply terminal 31 on the outer peripheral surface of the first placing table 2 facing the second placing table 7. For example, the insulating portion 33 enclosing the wiring 32 is provided along the outer peripheral surface from the flange portion 6e of the electrostatic chuck 6. The insulating portion 33 is formed of an insulator. For example, the insulating portion 33 is formed of a ceramic material such as, for example, alumina (Al₂O₃) ceramic. For example, the insulating portion 33 may be formed by stacking green sheets including, for example, a ceramic and then sintering the green sheets.

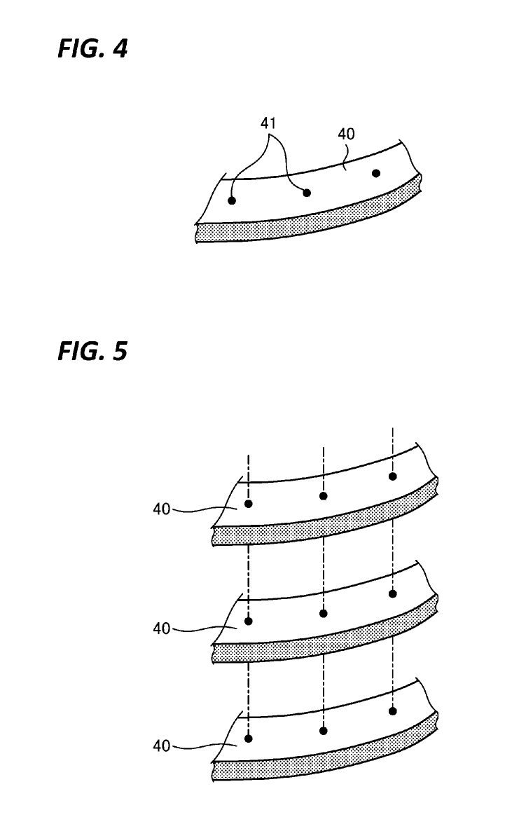

FIG. 4 is a plan view illustrating an exemplary green sheet. The green sheet 40 is formed of a ceramic material in a sheet shape, and conductive portions 41 made of a conductive material are provided to correspond to positions where the wiring 32 is provided. In the green sheet 40, the conductive portions 41 are provided to correspond to the positions where the wiring 32 is provided. The insulating portion 33 is formed by stacking the green sheets 40 with the positions of the conductive portions 41 being aligned and then sintering the green sheets 40. FIG. 5 is a view illustrating an example of a method for manufacturing an insulating portion. In the example of FIG. 5, three green sheets 40 are stacked with the positions of the conductive portions 41 being aligned. After being sintered with the positions being aligned, the conductive portions 41 function as the wirings 32.

The descriptions will refer back to FIG. 2. The insulating portion 33 may have a thermal conductivity lower than that of the first placing table 2. For example, the insulating portion 33 may have a thermal conductivity lower than that of the base 3. For example, in the plasma processing apparatus 10, the base 3 of the first placing table 2 is formed of aluminum, and the insulating portion 33 is formed of a sintered body of alumina ceramic. In this manner, when the thermal conductivity of the insulating portion 33 is lower than that of the first placing table 2, the insulating portion 33 functions as a heat insulating material. Thus, it is possible to suppress the heat during the plasma processing from being transmitted to the first placing table 2.

The insulating portion 33 is provided on the entire outer peripheral surface of the first placing table 2 in the circumferential direction. Therefore, the outer peripheral surface of the first placing table 2 may be protected from the plasma. In addition, the insulating portion 33 dispersedly encloses a plurality of wirings 32 connecting the plurality of heaters 6c and the plurality of power supply terminals 31 on the outer peripheral surface. Thus, even when a large number of heaters 6c are arranged on the placing surface 6d of the first placing table 2, the wirings 32 connecting the heaters 6c and the power supply terminals 31 may be arranged thereon. Further, the insulating portion 33 is formed with a gap 36 of a predetermined distance between the insulating portion 33 and the outer peripheral surface of the first placing table 2. Therefore, it is possible to suppress any influence caused by the difference in thermal expansion coefficient between the first placing table 2 and the insulating portion 33. The insulating portion 33 may be provided on a part of the outer peripheral surface of the first placing table 2 in the circumferential direction.

The power supply terminal 31 is connected to a heater power supply (not illustrated) via a wiring 35. The heaters 6c are supplied with power from the heater power supply under the control of the controller 90. The placing surface 6d is heated and controlled by the heaters 6c.

The second placing table 7 includes a base 8 and a focus ring heater 9. The focus ring heater 9 is attached to the base 8 via an insulating layer 49. The top surface of the focus ring heater 9 serves as a placing surface 9d on which the focus ring 5 is placed. The top surface of the focus ring heater 9 may be provided with, for example, a sheet member having high thermal conductivity.

The height of the second placing table 7 is appropriately adjusted such that the heat transfer or the RF power to the wafer W and the heat transfer or the RF power to the focus ring 5 coincide with each other. That is, FIG. 2 illustrates a case where the height of the placing surface 6d of the first placing table 2 and the height of the placing surface 9d of the second placing table 7 do not coincide with each other, but both heights may coincide with each other.

The focus ring 5 is an annular member and is provided to be coaxial with the second placing table 7. On the inner lateral surface of the focus ring 5, a convex portion 5a is formed to protrude inward in the radial direction. That is, the inner diameter of the focus ring 5 differs depending on the position of the inner lateral surface. For example, the inner diameter of a portion where the convex portion 5a is not formed is larger than the outer diameter of the wafer W and the outer diameter of the flange portion 6e of the electrostatic chuck 6. Meanwhile, the inner diameter of a portion where the convex portion 5a is formed is smaller than the outer diameter of the flange portion 6e of the electrostatic chuck 6 and is larger than the outer diameter of the portion where the flange portion 6e of the electrostatic chuck 6 is not formed.

The focus ring 5 is disposed on the second placing table 7 such that the convex portion 5a is separated from the top surface of the flange 6e of the electrostatic chuck 6 and also separated from the lateral surface of the electrostatic chuck 6. That is, a gap is formed between the lower surface of the convex portion 5a of the focus ring 5 and the top surface of the flange portion 6e of the electrostatic chuck 6. Further, a gap is formed between the lateral surface of the convex portion 5a of the focus ring 5 and the lateral surface on which the flange portion 6e of the electrostatic chuck 6 is not formed. The convex portion 5a of the focus ring 5 is positioned above a gap 34 between the insulating portion 33 and the base 8 of the second placing table 7. That is, when viewed from a direction orthogonal to the placing surface 6d, the convex portion 5a exists at a position overlapping the gap 34 and covers the gap 34. Therefore, it is possible to suppress the plasma from entering the gap 34 between the insulating portion 33 and the base 8 of the second placing table 7.

In the focus ring 9, a heater 9a is provided inside the insulator 9b. The heater 9a has an annular shape that is coaxial with the base 8. The heater 9a may be provided solely on the entire region of the placing surface 9d or may be provided individually for each divided region of the placing surface 9d. That is, a plurality of heaters 9a may be provided individually for respective divided regions of the placing surface 9d. For example, the placing surface 9d of the second placing table 7 may be divided into a plurality of regions according to the distance from the center of the second placing table 7, and the heater 9a may be provided for each region. For example, in FIG. 3, the placing surface 9d of the second placing table 7 is illustrated in a disc shape around the placing surface 6d of the first placing table 2. The placing surface 9d is divided into a plurality of regions HT2 according to the direction from the center, and the heater 9a is provided individually in each of the regions HT2. Therefore, the plasma processing apparatus 10 may control the temperature of the focus ring 5 for each of the regions HT2.

The descriptions will refer back to FIG. 2. The base 8 is provided with a power supply mechanism for supplying power to the heater 9a. This power supply mechanism will be described. A through hole HL is formed in the base 8 to penetrate the base 8 from the back surface to the top surface.

The focus ring heater 9 and the insulating layer 49 are provided with a contact 51 for power feeding. One end surface of the contact 51 is connected to the heater 9a. The other end surface of the contact 51 faces the through hole HL and is connected to the power supply terminal 52. The power supply terminal 52 is connected to a heater power supply (not illustrated) via a wiring 53. The heater 9a is supplied with power from the heater power supply under the control of the controller 90. The placing surface 6d is heated and controlled by the heater 9a. The power supply mechanism to the heater 9a of the focus ring heater 9 may be provided on the lateral surface side of the second placing table 7 similarly to the power supply mechanism to the heater 6c of the electrostatic chuck 6. For example, the power supply mechanism to the heater 9a of the focus ring heater 9 may be provided by providing a power supply terminal on the back surface side of the placing surface 9d and enclosing the wiring connecting the heater 9a and the power supply terminal in the insulator.

[Action and Effect]

Next, descriptions will be made on an action and an effect of a plasma processing apparatus 10 according to the present exemplary embodiment. In a plasma processing (e.g., etching), in order to implement the uniformity of the processing precision in the plane of the wafer W, it is required to adjust not only the temperature of the wafer W, but also the temperature of the focus ring 5 installed in the outer peripheral region of the wafer W. As an example, in the plasma processing apparatus 10, it is desired to set the set temperature of the focus ring 5 in a higher temperature range, compared with the set temperature of the wafer W, so as to obtain a temperature difference of, for example, 100 degrees or more.

Therefore, in the plasma processing apparatus 10, it is considered that the first placing table 2 on which the wafer W is placed and the second placing table 7 on which the focus ring 5 is placed are provided separately from each other so as to suppress the movement of heat. Therefore, the plasma processing apparatus 10 may individually adjust not only the temperature of the wafer W, but also the temperature of the focus ring 5. For example, in the plasma processing apparatus 10, the set temperature of the focus ring 5 may be set in a higher temperature range compared with the set temperature of the wafer W. Therefore, the plasma processing apparatus 10 may implement the uniformity of the processing precision in the plane of the wafer W.

Further, in the plasma processing apparatus 10, the power supply terminal 31 is provided on the back surface side opposite to the placing surface 6d of the first placing table 2. In addition, in the plasma processing apparatus 10, the insulating portion 33 enclosing the wiring 32 connecting the heater 6c and the power supply terminal 31 is provided on the outer peripheral surface of the first placing table 2.

Here, for example, in the plasma processing apparatus 10, in order to reduce the overlapping portion between the first placing table 2 and the focus ring 5, it is conceivable that a through hole is formed in the lower portion of the heater 6c of the first placing table 2 to supply power to the heater 6c. However, in the plasma processing apparatus 10, when the through hole is formed in the first placing table 2 to supply power to the heater 6c, the portion of the placing surface 6d where the through hole is formed becomes a singular point where the uniformity of heat decreases, so that the in-plane uniformity of the plasma processing on the wafer W decreases.

Meanwhile, in the plasma processing apparatus 10, the wiring 32 connecting the heater 6c and the power supply terminal 31 is provided on the outer peripheral surface of the first placing table 2. As a result, the plasma processing apparatus 10 may supply power to the heater 6c without forming a through hole in the first placing table 2. Thus, it is possible to suppress a deterioration of the in-plane uniformity of the plasma processing on the wafer W. In addition, in the plasma processing apparatus 10, the power supply terminal 31 is provided on the back surface side opposite to the placing surface 6d, and the insulating portion 33 enclosing the wiring 32 connecting the heater 6c and the power supply terminal 31 is provided on the outer peripheral surface of the first placing table 2. As a result, in the plasma processing apparatus 10, the overlapping portion between the focus ring 5 and the insulating portion 33 may be reduced. Thus, it is possible to suppress occurrence of unevenness in the temperature of the focus ring 5 in the radial direction. In addition, it is possible to suppress a reduction in the in-plane uniformity of the plasma processing on the wafer W.

Further, in the plasma processing apparatus 10, the heater 9a is provided on the placing surface 9d on which the focus ring 5 of the second placing table 7 is placed. Therefore, the plasma processing apparatus 10 may individually adjust not only the temperature of the wafer W, but also the temperature of the focus ring 5. Thus, it is possible to enhance the in-plane uniformity of processing precision of the wafer W. For example, in the plasma processing apparatus 10, the set temperature of the focus ring 5 may be set in a higher temperature range, compared with the set temperature of the wafer W, so as to obtain a temperature difference of, for example, 100 degrees or more. Therefore, the plasma processing apparatus 10 may implement high in-plane uniformity of processing precision of the wafer W.

Further, in the plasma processing apparatus 10, the coolant flow path 2d is formed inside the first placing table 2. Since the plasma processing apparatus 10 may control the temperature of the wafer W by causing the coolant to flow through the coolant flow path 2d, it is possible to improve the processing precision of the wafer W by the plasma processing.

As described above, the plasma processing apparatus 10 according to the present exemplary embodiment may achieve both the in-plane uniformity of temperature of the wafer W and the controllability of the temperature difference between the wafer W and the focus ring 5.

Further, in the plasma processing apparatus 10, the heater 6c is individually provided for each region obtained by dividing the placing surface 6d of the first placing table 2. Further, in the plasma processing apparatus 10, a plurality of power supply terminals 31 are provided on the back surface side opposite to the placing surface 6d of the first placing table 2. In the plasma processing apparatus 10, the insulating portion 33 is formed in a ring shape to surround the outer peripheral surface of the first placing table 2. In the insulating portion 33, a plurality of wirings 32 connecting the plurality of heaters 6c and the plurality of power supply terminals 31 are dispersedly enclosed in the outer peripheral surface. As a result, in the plasma processing apparatus 10, even when a large number of heaters 6c are arranged on the placing surface 6d of the first placing table 2, the wirings 32 connecting the heaters 6c and the power supply terminals 31 may be arranged thereon.

Further, in the plasma processing apparatus 10, the insulating portion 33 is formed of ceramics having a thermal conductivity lower than that of the first placing table 2. As a result, in the plasma processing apparatus 10, the insulating portion 33 functions as a heat insulating material. Thus, it is possible to suppress the heat from being transferred to the first placing table 2 during the plasma processing.

Further, the insulating portion 33 of the plasma processing apparatus 10 is formed by stacking and sintering sheet-like ceramic materials (green sheets 40) each provided with a conductive portion 41 that functions as a wiring 32. The green sheets 40 have a high insulating property. Therefore, the plasma processing apparatus 10 may maintain the insulation property of the insulating portion 33 even when the power flowing through the wiring 32 is increased in order to increase the heat generation amount of the heater 6.

### Second Exemplary Embodiment

Next, a second exemplary embodiment will be described. Since the plasma processing apparatus 10 according to the second exemplary embodiment is the same as the plasma processing apparatus 10 according to the first exemplary embodiment illustrated in FIG. 1, its descriptions will be omitted.

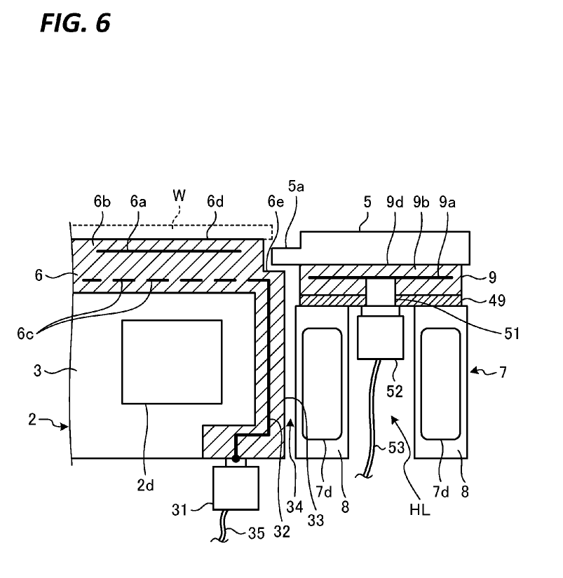

Next, descriptions will be made on the configuration of the main part of the first placing table 2 and the second placing table 7 according to a first exemplary embodiment with reference to FIG. 6. FIG. 6 is a schematic cross-sectional view illustrating the configuration of the main part of first and second placing tables according to the second exemplary embodiment. The first placing table 2 and the second placing table 7 according to the second exemplary embodiment are partially similar to the first placing table 2 and the second placing table 7 according to the first exemplary embodiment illustrated in FIG. 2. Therefore, the same parts are denoted by the same reference numerals, and the description thereof will be omitted. Mainly, different parts will be described.

The first placing table 2 includes a base 3 and an electrostatic chuck 6. The electrostatic chuck 6 according to the second exemplary embodiment is formed by a thermally sprayed film obtained by alternately thermally spraying an insulating material (e.g., an insulating ceramic) and a conductive material (e.g., a conductive metal) onto the base 3, and includes an electrode 6a, an insulator 6b, and a heater 6c. The insulator 6b is formed of a thermally sprayed film of an insulating material. The electrode 6a and the heater 6c are formed of a thermally sprayed film of a conductive material. Further, the heater 6c may be provided solely on the entire region of the placing surface 6d or may be provided individually for each divided region HT1 of the placing surface 6d.

The first placing table 2 is provided with a power supply terminal 31 on the back surface side opposite to the placing surface 6d. The power supply terminal 31 is provided to correspond to the heater 6c provided on the placing surface 6d. The first placing table 2 is provided with an insulating portion 33 enclosing a wiring 32 connecting the heater 6c and the power supply terminal 31 on the outer peripheral surface of the first placing table 2 facing the second placing table 7. For example, the insulating portion 33 enclosing the wiring 32 is provided along the outer peripheral surface from the flange portion 6e of the electrostatic chuck 6.

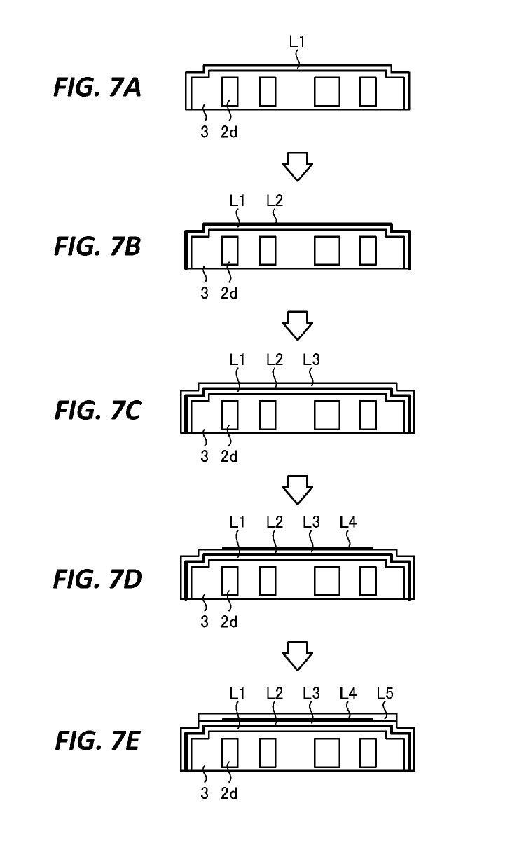

Here, descriptions will be made on a method for manufacturing the electrostatic chuck 6 and the insulating portion 33 according to the second exemplary embodiment. FIGS. 7A to 7E are views for explaining a method for manufacturing an electrostatic chuck and an insulating portion according to the second exemplary embodiment. FIGS. 7A to 7E illustrate a flow of manufacturing the electrostatic chuck 6 and the insulating portion 33.

First, as illustrated in FIG. 7A, an insulating ceramic is thermally sprayed on the top surface and the lateral surface of the base 3 so as to form an insulating layer L1 of a thermally sprayed film of the insulating ceramic on the top surface and the lateral surface of the base 3. Examples of the insulating ceramic include alumina and yttria.

Next, as illustrated in FIG. 7B, a conductive metal is thermally sprayed on the insulating layer L1 so as to form a conductive layer L2 of a thermally sprayed film of the conductive metal on the entire insulating layer L1, and unnecessary portions of the conductive layer L2 are removed by, for example, blasting or polishing, thereby forming the heater 6c and the wiring 32 in the conductive layer L2. Examples of the conductive metal include tungsten. The heater 6c and the wiring 32 may be formed by disposing a pattern corresponding to the heater 6c and the wiring 32 on the insulating layer L1 of the base 3 and forming the conductive layer L2 by thermal spraying of the conductive metal.

Next, as illustrated in FIG. 7C, an insulating ceramic is thermally sprayed on the conductive layer L2 so as to form an insulating layer L3 of a thermally sprayed film of the insulating ceramic on the top surface and the lateral surface of the base 3.

Next, as illustrated in FIG. 7D, a conductive metal is thermally sprayed on the insulating layer L3 so as to form a conductive layer L4 of a thermally sprayed film of the conductive metal on the entire insulating layer L3, and unnecessary portions of the conductive layer L4 are removed by, for example, blasting or polishing, thereby forming the electrode 6a in the conductive layer L4. The electrode 6a may be formed by disposing a pattern corresponding to the electrode 6a on the insulating layer L3 and forming the conductive layer L4 by thermal spraying of the conductive metal.

Next, as illustrated in FIG. 7E, an insulating ceramic is thermally sprayed on the conductive layer L4 so as to form an insulating layer L5 of a thermally sprayed film of the insulating ceramic on the top surface and the lateral surface of the base 3.

Pinholes may be provided in a layer lower than the electrode 6a of the electrostatic chuck 6 and in the base 3. The electrode 6a may be supplied with power from the DC power supply 12 via power supply terminals arranged in the pinholes. Further, similarly to the wiring 32, a wiring for power supply may be formed in the conductive layer L4. Then, the electrode 6a may be supplied with power from the DC power supply 12 via the wiring for power supply formed in the conductive layer L4.

Since the insulating layers L1, L3, and L5 and the conductive layers L2 and L4 formed by thermal spraying are porous, cracks do not occur even when the base 3 expands and contracts due to a temperature change. Thus, the insulating layers L1, L3, and L5 and the conductive layers L2, and L4 may withstand expansion and contraction.

Further, the thermal spraying is inexpensive. Therefore, when the electrostatic chuck 6 and the insulating portion 33 are fabricated by thermal spraying, the electrostatic chuck 6 and the insulating portion 33 may be formed at a low cost.

In the second exemplary embodiment, descriptions have been made on the case where the electrostatic chuck 6 and the insulating portion 33 are fabricated by thermal spraying at once, but the present disclosure is not limited thereto. The electrostatic chuck 6 and the insulating portion 33 may be separately fabricated. Further, a part or all of the electrostatic chuck 6 may be formed by sintering an insulating ceramic plate. For example, the electrostatic chuck 6 and the insulating portion 33 may be formed by thermally spraying the insulating layers L1 and L3 and the conductive layers L2 and L4, and the insulating layer L5 may be formed by sintering an insulating ceramic plate. Further, the electrostatic chuck 6 may be formed by sintering, for example, an insulating ceramic plate, and the insulating portion 33 may be formed by thermal spraying.

[Action and Effect]

As described above, the insulating portion 33 of the plasma processing apparatus 10 includes a conductive layer L2, which functions as the wiring, formed by thermal spraying of a conductive metal, in the insulating layers (between the insulating layers L1 and L3) formed by thermal spraying of a conductive metal. Therefore, even when the base 3 expands and contracts, the plasma processing apparatus 10 may withstand without occurrence of, for example, cracks. Further, in the plasma processing apparatus 10, the electrostatic chuck 6 and the insulating portion 33 may be fabricated at a low cost.

As such, various exemplary embodiments have been described, but various modifications may be made without being limited to the exemplary embodiments described above. For example, the above-described plasma processing apparatus 10 is a capacitively coupled plasma processing apparatus 10, but the first placing table 2 may be employed in an arbitrary plasma processing apparatus 10. For example, the plasma processing apparatus 10 may be any type of plasma processing apparatus 10, such as an inductively coupled plasma processing apparatus 10 or a plasma processing apparatus 10 for exciting a gas with surface waves (e.g., microwaves).

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a first placing table including a placing surface configured to place thereon a workpiece serving as a plasma processing target, an outer peripheral surface, a heater provided on the placing surface, a power supply terminal provided on a back surface side opposite to the placing surface, and a wiring provided on the outer peripheral surface so as to be enclosed in an insulator, the wiring being configured to connect the heater and the power supply terminal; and
a second placing table provided along the outer peripheral surface of the first placing table and configured to place a focus ring thereon.

2. The plasma processing apparatus of claim 1, wherein the second placing table includes a heater provided on a placing surface on which the focus ring is placed.

3. The plasma processing apparatus of claim 2, wherein the first placing table includes a coolant flow path formed therein.

4. The plasma processing apparatus of claim 1, wherein, in the first placing table, a plurality of heaters are provided individually for respective regions obtained by dividing the placing surface, and a plurality of power supply terminals are provided on the back surface side, and
the insulator is formed in a ring shape so as to surround the outer peripheral surface of the first placing table, and a plurality of wirings connecting the plurality of heaters and the plurality of power supply terminals are provided on the outer peripheral surface so as to be dispersedly enclosed in the insulator.

5. The plasma processing apparatus of claim 1, wherein the insulator is formed of a ceramic having a thermal conductivity lower than that of the first placing table.

6. The plasma processing apparatus of claim 1, wherein the insulator is formed with a gap of a predetermined distance between the insulator and the outer peripheral surface.

7. The plasma processing apparatus of claim 1, wherein the insulator is formed by stacking and sintering sheet-like ceramic materials each provided with a conductive portion serving as the wiring.

8. The plasma processing apparatus of claim 1, wherein the insulator includes a conductive layer configured to function as the wiring and formed by thermal spraying of a conductive metal in an insulating layer formed by thermal spraying of a conductive metal.
